(19) United States
(12) Patent Application Publication
(10) Pub. No.: US 2008/0157374 A1
(43) Pub. Date: Jul. 3, 2008

(54) SEMICONDUCTOR DEVICE AND FABRICATING METHOD THEREOF

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/873,946

(22) Filed: Oct. 17, 2007

(30) Foreign Application Priority Data
Dec. 27, 2006 (KR) 10-2006-0135746

(51) Int. Cl. H01L 23/52; H01L 21/60

(52) U.S. Cl. 257/751; 438/107; 257/E23.141; 257/E21.506

(57) ABSTRACT

A semiconductor device including an integrated device having a first device having a first pad part formed on a top metal layer, a second device arranged at the circumference of the first device and having a second pad part formed on the top metal layer, a connecting electrode electrically connecting the first pad part to the second pad part; and a bonding pad part connected the integrated device and connecting signals to the external.

The present application claims priority under 35 U.S.C. 119 and 35 U.S.C. 365 to Korean Patent Application No. 10-2006-0135746 (filed on Dec. 27, 2006), which is hereby incorporated by reference in its entirety.

### BACKGROUND

Aspects of semiconductor technology have focused on the integration of semiconductor devices using system on chip (SoC) technology integrating RF, CPU, CMOS sensor, etc., into a single chip. However, integrating several different semiconductor devices having various design rules into a single chip can be difficult to achieve.

System-in-package (SiP) technology can achieve a highly integrated IC in a system level using a scheme integrating different parts or ICs into a single package. However, several problems exists, such as the fabrication of a through electrode, heat emission of an intermediate layer device, and the elimination of noise between electrodes, etc.

Currently, a method of fabricating semiconductor devices by integrating each device on a PCB substrate through sawing and wire bonding has been implemented. This method, however, can be disadvantageous due in part that it requires space making it difficult to obtain high integration and creates noise during wire bonding and an interconnection of the PCB substrate.

### SUMMARY OF THE INVENTION

Embodiments relate to method of fabricating a semiconductor device that is efficient and can achieve a highly integrated device in a system level.

Embodiments relate to a semiconductor device including a first device having a first pad part formed on a top metal layer, a second device arranged at the outer periphery of the first device and having a second pad part formed on and/or over the top metal layer, a connecting electrode electrically connecting the first pad part to the second pad part; and a bonding pad part connected the integrated device and connecting signals to the external.

Embodiments relate to a method of fabricating a semiconductor device including at least one of the following steps: forming a first device having a first pad part formed on and/or over a top metal layer and a second device having a second pad part formed on and/or over the top metal layer; arranging the second device at the outer periphery of the first device and forming a connecting electrode electrically connecting the first pad part to the second pad part to fabricate an integrated device; forming a protective layer on and/or over the integrated device; and opening a bonding pad part connected to the integrated device through the etch for the protective layer and connecting signals to the external.

### DRAWINGS

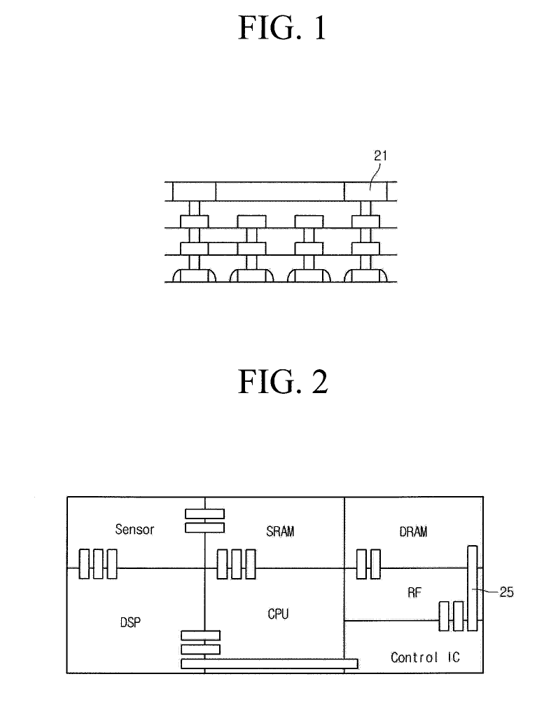

Example FIGS. 1 to 5 illustrate a method of fabricating a semiconductor device in a SBI scheme, in accordance with embodiments.

### DESCRIPTION

In the description of the embodiment, when each layer (film), an area, a pattern or structures are described to be formed “on/above” or “below/under” each layer (film), the area, the pattern or the structures, it can be understood as the case that each layer (film), an area, a pattern or structures are formed by being directly contacted to each layer (film), the area, the pattern or the structures and it can further be understood as the case that other layer (film), other area, other pattern or other structures are additionally formed therebetween. Therefore, the meanings should be judged according to the technical idea of the embodiment.

In accordance with embodiments, a highly integrated IC fabricating method using system by interconnection (SBI) that fabricates each individual semiconductor device on different wafers and then connecting each device using a metal interconnection method. Using SBI, a plurality of devices can form a semiconductor device.

As illustrated in example FIG. 2, SBI integrates semiconductor devices performing a metal interconnection of each device (CPU, SRAM, DRAM, Flash Memory, Logic Devices, Power IC, Control IC, Sensor Chip, etch) fabricated on different wafers through connecting electrode 25 to integrate the devices.

As illustrated in example FIG. 1, each unit device can be formed by designing pad part 21 that can be electrically connected to other devices on and/or over a top metal layer.

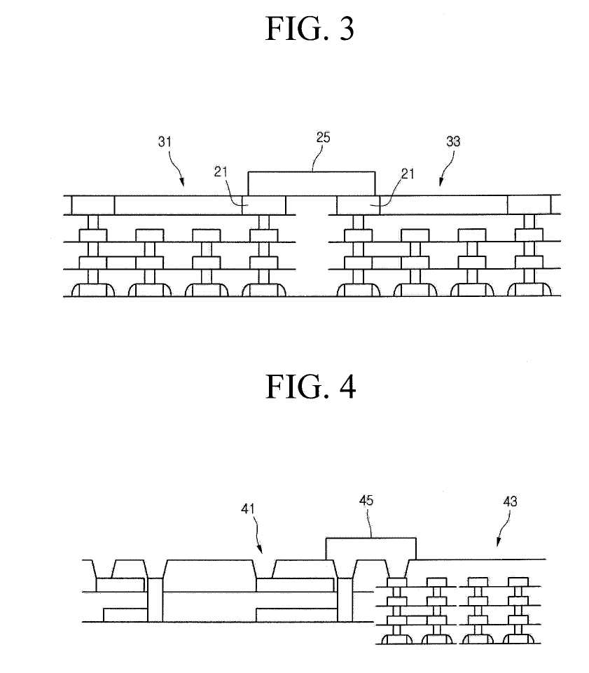

As illustrated in example FIG. 3, using SBU, first device 31 and second device 33 can be fabricated on and/or over separate semiconductor substrates and can be electrically connected by connecting electrode 25. Pad part 21 can be used to interconnect “device to device” to different wafers can fabricate the unit devices (CPU, SRAM, DRAM, Flash Memory, Logic Devices, Power IC, Control IC, Sensor Chip, etc) formed on and/or over a top metal layer.

Such unit devices can be arranged such that first device 31 can be arranged at the outer periphery of second device 33. Instead of using a vertical arrangement structure, the spatial positioning of first device 31 and second device 33 can be accomplished in a horizontal arrangement. The uppermost surfaces of first device 31 and second device 33 can be substantially parallel, i.e., formed at the same height and/or lie in the same plane.

Using SBI, the metal interconnection between devices is accomplished by aligning each unit device and forming them on and/or over a metal layer. Next, a photoresist is patterned on and/or over the metal layer and then etched in order to obtain metal interconnection. A protective layer can then be formed on and/or over the resultant device.

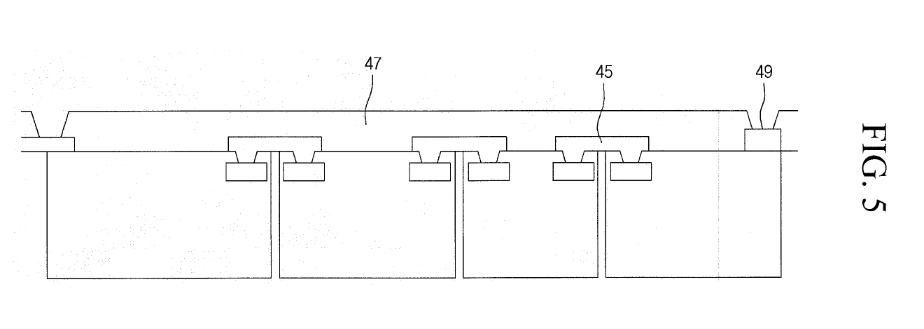

As illustrated in example FIGS. 4 and 5, first device 41 and second 43 may each have a pad part formed on and/or over the top metal layer and a protective layer formed thereon and/or thereover. The pad part may be exposed in order to connect first device 41 to second device 43. First device 41 and second device 43 can be electrically connected or otherwise aligned using an interconnection method whereby a metal layer can be formed on and/or over each device 41, 43. A photoresist can then be patterned on and/or over the metal layer and etched to obtain connecting electrode 45. Connecting electrode 45 can be formed of materials selected from a group consisting of Al, Ti/TiN/Al/Ti/TiN, Ti/Al/Ti/TiN, Ti/Al/TiN, Ti/TiN/Al/Ti, Ti/TiN/Al/TiN, Cu, TaN/Cu/TaN.

Protective layer 47 can be formed on and/or over connecting electrode 45. Protective layer 47 may be etched in order to expose at least a portion of the uppermost surface of bonding pad part 49 electrically connected to each device and used for connecting to the external.

The semiconductor devices may be selected from a group including an image sensor, a device having a capacitor cell, a device having an inductor cell, a CPU, an SRAM, a DRAM, a Flash Memory, Logic Devices, a Power IC, a Control IC, and a Sensor Chip.

In accordance with embodiments, a semiconductor device can include an integrated device having first device 41 having a first pad part formed on and/or over a top metal layer, second device 43 arranged at the outer periphery of first device 41 and having a second pad part formed on and/or over the top metal layer, and connecting electrode 45 electrically connecting the first pad part to the second pad part. A bonding pad part may be included to eternally connect the integrated device and connecting signals.

In accordance with embodiments, a semiconductor device can include an integrated device having first device 41 having a first pad part formed on and/or over a top metal layer, second device 43 arranged at the outer periphery of first device 41 and having a second pad part formed on and/or over the top metal layer, connecting electrode 45 electrically connecting the first pad part to the second pad part, protective layer 47 formed on and/or over first device 41, second device 43 and connecting electrode 45. A bonding pad part may be included to externally connect the integrated device and connecting signals. Moreover, the uppermost surfaces of first device 41 and second device 43 can be formed at the same height, i.e., substantially parallel with respect to each other.

The semiconductor devices may be selected from a group including an image sensor, a device having a capacitor cell, a device having an inductor cell, a CPU, an SRAM, a DRAM, a Flash Memory, Logic Devices, a Power IC, a Control IC, and a Sensor Chip.

In accordance with embodiments, each individual device can be connected using system by interconnection (SBI) so that the resultant integrated device can be further efficiently formed. Furthermore, the heat emission problems associated stacked devices in a SiP form can be easily solved. Moreover, the semiconductor device can be advantageous for providing a more efficient and simplistic fabricating process to obtain a highly integrated device in a system level.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
an integrated device including a first semiconductor device having a first pad formed over a metal layer, a second semiconductor device arranged at the outer periphery of the first semiconductor device and having a second pad formed over the metal layer, and a connecting electrode electrically connecting the first pad to the second pad; and
a bonding pad connected to the integrated device.

2. The apparatus of claim 1, further comprising a protective layer formed over the first semiconductor device, the second semiconductor device, and the connecting electrode.

3. The apparatus of claim 1, wherein the uppermost surfaces of the first semiconductor device and the second semiconductor device have the same height.

4. The apparatus of claim 1, wherein the first semiconductor device and the second semiconductor device are semiconductor devices selected from a group consisting of an image sensor, a semiconductor device having a capacitor cell, a semiconductor device having an inductor cell, a CPU, an SRAM, a DRAM, a Flash Memory, Logic Devices, a Power IC, a Control IC and a Sensor Chip.

5. The apparatus of claim 1, wherein the connecting electrode comprises materials selected from a group consisting of Al, Ti/TiN/Al/Ti/TiN, Ti/Al/Ti/TiN, Ti/Al/TiN, Ti/TiN/Al/Ti, Ti/TiN/Al/TiN, Cu and TaN/Cu/TaN.

6. The apparatus of claim 1, wherein the connecting electrode comprises a multilayer structure.

7. The apparatus of claim 6, wherein the multilayer structure comprises one selected from a group consisting of Ti/TiN/Al/Ti/TiN, Ti/Al/Ti/TiN, Ti/Al/TiN, Ti/TiN/Al/Ti, Ti/TiN/Al/TiN and TaN/Cu/TaN.

8. A method comprising:
forming a first device having a first pad formed over a metal layer and a second device having a second pad formed over the metal layer;
arranging the second device at the outer periphery of the first device;
providing an integrated device by forming a connecting electrode electrically connecting the first pad to the second pad;
electrically connecting a bonding pad to the integrated device;
forming a protective layer over the integrated device; and then
exposing at least a portion of the uppermost surface of the bonding pad by etching the protective layer.

9. The method of claim 8, wherein the uppermost surfaces of the first device and the second device are arranged at the same height.

10. The method of claim 8, wherein the first device and the second device are devices selected from a group consisting of an image sensor, a device having a capacitor cell, a device having an inductor cell, a CPU, an SRAM, a DRAM, a Flash Memory, Logic Devices, a Power IC, a Control IC and a Sensor Chip.

11. The method of claim 8, wherein the connecting electrode is formed of materials selected from a group consisting of Al, Ti/TiN/Al/Ti/TiN, Ti/Al/Ti/TiN, Ti/Al/TiN, Ti/TiN/Al/Ti, Ti/TiN/Al/TiN, Cu and TaN/Cu/TaN.

12. The method of claim 11, wherein the connecting electrode comprises a multilayer structure.

13. The method of claim 12, wherein the multilayer structure comprises one selected from a group consisting of Ti/TiN/Al/Ti/TiN, Ti/Al/Ti/TiN, Ti/Al/TiN, Ti/TiN/Al/Ti, Ti/TiN/Al/TiN and TaN/Cu/TaN.

14. A method comprising:
forming a plurality of semiconductor devices;
providing an integrated device by electrically connecting the plurality of semiconductor devices;
electrically connecting a bonding pad to the integrated device;
forming a protective layer over the integrated device; and then
exposing at least a portion of the uppermost surface of the bonding pad.
forming a second semiconductor device having a second pad over the second semiconductor substrate;
forming a connecting electrode having a multilayer structure to electrically connect the first semiconductor device to the second semiconductor device;
forming a bonding pad over the metal layer.

15. The method of claim 14, wherein each one of the plurality of semiconductor devices has a pad formed over a metal layer.

16. The method of claim 15, wherein electrically connecting the plurality of semiconductor devices comprises electrically connecting the respective pads of the plurality of semiconductor devices.

17. The method of claim 14, further comprising spatially positioning the plurality of semiconductor devices laterally with respect to each other prior to electrically connecting the plurality of semiconductor devices.

18. The method of claim 17, wherein the uppermost surface of each one of the plurality of semiconductor devices lie substantially in the same plane.

19. The method of claim 14, wherein forming the connecting electrode comprises patterning a photoresist over the metal layer and etching the photoresist.

20. The method of claim 14, wherein the plurality of semiconductor devices are semiconductor devices selected from a group consisting of an image sensor, a device having a capacitor cell, a device having an inductor cell, a CPU, an SRAM, a DRAM, a Flash Memory, Logic Devices, a Power IC, a Control IC and a Sensor Chip.
